(19) United States
(12) Patent Application Publication
(10) Pub. No.: US 2022/0310674 A1
(43) Pub. Date: Sep. 29, 2022

(54) SEMICONDUCTOR DEVICE AND METHOD OF MANUFACTURING SEMICONDUCTOR DEVICE

(71) Applicant: Panasonic Intellectual Property Management Co., Ltd., Osaka (JP)

(72) Inventors: Kentaro NAKANISHI, Nara (JP); Tatsuya KABE, Osaka (JP); Mitsuyoshi MORI, Kyoto (JP); Shigeru SAITOU, Kyoto (JP)

(21) Appl. No.: 17/840,167

(22) Filed: Jun. 14, 2022

Related U.S. Application Data
(63) Continuation of application No. PCT/JP2020/044735, filed on Dec. 1, 2020.

(30) Foreign Application Priority Data
Dec. 27, 2019 (JP) 2019-238445

(51) Int. Cl. H01L 27/146

(52) U.S. Cl. CPC H01L 27/1462; H01L 27/14645; H01L 27/14621; H01L 27/14689; H01L 27/14685

(57) ABSTRACT

A semiconductor device includes a semiconductor substrate a pixel region in which an APD is disposed, and a logic region different from the pixel region; a transistor which is disposed in the logic region and includes a sidewall made of an insulating material; an anti-reflective film which is disposed above a main surface of the semiconductor substrate in the pixel region and is made of the insulating material; and a first liner film which is disposed above the main surface of the semiconductor substrate in the logic region and is made of the insulating material. The anti-reflective film and the first liner film are integrally formed. The thickness of the anti-reflective film is larger than or equal to the sum of the thickness of the sidewall and the thickness of the first liner film.

### CROSS REFERENCE TO RELATED APPLICATIONS

This is a continuation application of PCT International Application No. PCT/JP2020/044735 filed on Dec. 1, 2020, designating the United States of America, which is based on and claims priority of Japanese Patent Application No. 2019-238445 filed on Dec. 27, 2019. The entire disclosures of the above-identified applications, including the specifications, drawings and claims are incorporated herein by reference in their entirety.

### FIELD

The present disclosure relates to a semiconductor device including a photoelectric converter, and a method of manufacturing the semiconductor device.

### BACKGROUND

Avalanche photodiodes (APDs) are known as photodiodes effective under weak photon environments (for example, see Patent Literature (PTL) 1).

The APD as one example of a photoelectric converter disclosed in PTL 1 can detect light under weak photon environments by multiplying carriers, which are generated in a light absorption region, in an avalanche multiplication region. Moreover, to improve light collection efficiency, the APD disclosed in PTL 1 includes an anti-reflective film which suppresses reflection of incident light, the anti-reflective film being disposed above a surface of a silicon substrate including a light absorption region.

### CITATION LIST

### Patent Literature

PTL 1: Japanese Patent No. 4131191

### SUMMARY

### Technical Problem

The present disclosure provides a semiconductor device which can improve light collection efficiency and suppress generation of dark current, and the like.

### Solution to Problem

The semiconductor device according to one aspect of the present disclosure is a semiconductor device including: a silicon semiconductor substrate including a first region in which a photoelectric converter is disposed, and a second region different from the first region; a transistor which is disposed in the second region and includes a sidewall made of an insulating material; an anti-reflective film which is disposed above a main surface of the silicon semiconductor substrate in the first region and is made of the insulating material; and a first liner film which is disposed above the main surface of the silicon semiconductor substrate in the second region and is made of the insulating material. Here, the anti-reflective film and the first liner film are integrally formed, and a thickness of the anti-reflective film is larger than or equal to a sum of a thickness of the sidewall and a thickness of the first liner film.

The method of manufacturing a semiconductor device according to one aspect of the present disclosure is a method of manufacturing a semiconductor device, the method including: (i) forming a photoelectric converter in a first region in a silicon semiconductor substrate; (ii) forming a gate electrode in a second region different from the first region in the silicon semiconductor substrate, the gate electrode being included in a transistor; (iii) forming an insulating film by depositing an insulating material above a main surface of the silicon semiconductor substrate; (iv) forming a sidewall made of the insulating material in sides of the gate electrode by etching the insulating film; and (v) forming an anti-reflective film and a first liner film by further depositing the insulating material above the main surface of the silicon semiconductor substrate, the anti-reflective film being disposed above the main surface of the silicon semiconductor substrate in the first region and made of the insulating material, the first liner film being disposed above the main surface of the silicon semiconductor substrate in the second region and made of the insulating material.

### Advantageous Effects

The present disclosure can provide a semiconductor device which can improve light collection efficiency and suppress generation of dark current.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a cross-sectional view illustrating a semiconductor device according to an embodiment.

FIG. 2A is a cross-sectional view illustrating a method of manufacturing a semiconductor device according to an embodiment.

FIG. 2B is a cross-sectional view illustrating the method of manufacturing a semiconductor device according to the embodiment,

FIG. 2C is a cross-sectional view illustrating the method of manufacturing a semiconductor device according to the embodiment,

FIG. 2D is a cross-sectional view illustrating the method of manufacturing a semiconductor device according to the embodiment.

FIG. 2E is a cross-sectional view illustrating the method of manufacturing a semiconductor device according to the embodiment.

FIG. 3A is a cross-sectional view illustrating a method of manufacturing a semiconductor device according to Comparative Example.

FIG. 3B is a cross-sectional view illustrating the method of manufacturing a semiconductor device according to Comparative Example.

### DESCRIPTION OF EMBODIMENTS

Hereinafter, embodiments according to the present disclosure will be described with reference to the drawings. The embodiments described below all illustrate comprehensive or specific examples, Numeric values, shapes, materials, components, arrangement positions of components, connections forms, and the like shown in the embodiments below are exemplary, and should not be construed as limitations to the present disclosure. Among the components of the embodiments below, components not described in an independent claim showing an implementation form according to one aspect of the present disclosure will be described as optional components. Moreover, the implementation form according to the present disclosure is not limited to the present independent claim, but can also be represented by other independent claims.

The drawings are schematic views, and are not necessarily precise illustrations. In the drawings, identical referential signs will be given to substantially identical configurations, and overlapping descriptions will be omitted or simplified.

In this specification, terms “upper (above)” and “lower (under)” do not represent upper (vertically upper) and lower (vertically lower) directions in absolute spatial recognition, and are used as terms defined by relative positional relations based on the lamination order of a laminate structure. The terms “upper” and “lower” are used not only in cases where two components are spaced from each other and another component is present between the two components, but also in cases where two components are arranged adjacent to each other and are in contact with each other.

In the drawings used in description of the embodiments below, coordinate axes are shown in some cases. The Z-axial direction in the coordinate axes is the stacking direction and the vertical direction, for example. The positive Z-axial direction (side) is referred to as upper (upper side) and the negative Z-axial direction (side) is referred to as lower (lower side) in some cases. In other words, the Z-axial direction corresponds to a direction vertical to a main surface (surface above which a light collector is disposed) of a semiconductor substrate above which a photoelectric converter is disposed, and is also referred to as stacking direction. The X-axial direction and the Y-axial direction are directions intersecting perpendicular to each other in a plane orthogonal to the Z-axial direction (e.g., a horizontal plane).

In the embodiments below, the term “seen in planar view” means that the semiconductor device is viewed from the Z-axial direction.

Moreover, the present disclosure also covers structures in which the conductivity types described in the embodiments below are inverted. Specifically, the P-type and the N-type described below all may be inverted.

### Embodiments

### [Structure]

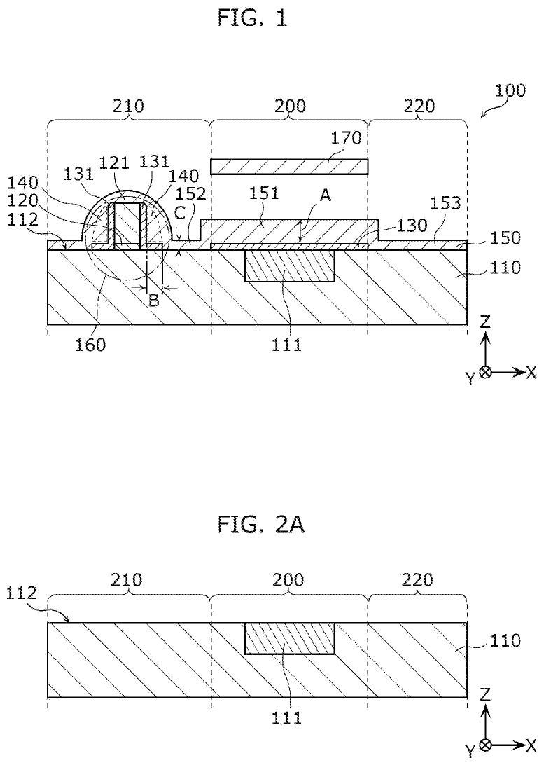

FIG. 1 is a cross-sectional view illustrating semiconductor device 100 according to an embodiment.

Semiconductor device 100 is a photodetector which detects incident light.

Semiconductor device 100 includes semiconductor substrate (silicon semiconductor substrate) 110, transistor 160, underlying oxide film 130, anti-reflective film 151, first liner film 152, second liner film 153, and color filter 170.

Semiconductor substrate 110 is a silicon semiconductor substrate in which a photoelectric conversion region such as photoelectric converter (APD) 111 is disposed, Semiconductor substrate 110 includes pixel region (first region) 200, logic region (second region) 210, and another region (third region) 220. Pixel region 200, logic region 210, and another region 220 are different regions from each other in semiconductor substrate 110.

Pixel region 200 is a region in which APD 111 is disposed. Pixel region 200 includes underlying oxide film 130 and anti-reflective film 151 disposed above main surface 112 of semiconductor substrate 110.

In the present embodiment, the term “above main surface 112” indicates that a component is located in the positive Z-axial direction with respect to main surface 112, and means both of the case where the component is in contact with main surface 112 and the case where the component is not in contact with main surface 112.

APD 111 is a photoelectric converter which photoelectrically converts incident light. For example, APD 111 is an avalanche photodiode including an avalanche multiplication region in which electrons generated through photoelectric conversion are subjected to avalanche multiplication, APD 111 may be a photodiode (PD) without the avalanche multiplication region.

In the present embodiment, APD 111 photoelectrically converts light having a wavelength of 650 nm or more. For example, the material for semiconductor substrate 110 is selected such that APD 111 photoelectrically converts light having a wavelength of 650 nm or more. In the present embodiment, because semiconductor substrate 110 is a silicon semiconductor substrate, APD 111 absorbs and photoelectrically converts light having a wavelength of 650 nm or more.

Underlying oxide film 130 is disposed in semiconductor substrate 110 in contact with main surface 112. Underlying oxide film 130 is a silicon oxide film, for example.

Anti-reflective film 151 is a film for preventing (suppressing) light entering APD 111 from being reflected from main surface 112. Anti-reflective film 151 is made of an insulating material. The insulating material has electrical insulation. Insulating material is a nitride, for example. In other words, anti-reflective film 151 is a film made of a nitride (nitride film), for example, Specifically, anti-reflective film 151 is a silicon nitride film, for example. Anti-reflective film 151 is disposed above main surface 112 of semiconductor substrate 110 in pixel region 200, i.e., above pixel region 200.

Thickness A of anti-reflective film 151 is set according to the wavelength of the target light to be prevented from being reflected. Thickness A of anti-reflective film 151 is 70 nm or more, for example. In such a configuration, anti-reflective film 151 reduces reflection of light having a wavelength of 650 nm or more, for example.

Logic region 210 is a region in which transistor 160 is disposed. In the present embodiment, logic region 210 includes transistor 160 and first liner film 152.

Transistor 160 is a transistor disposed in logic region 210, The components included in transistor 160 and disposed in semiconductor substrate 110, such as a source and a drain, are not illustrated. Transistor 160 is used in a transfer transistor, a reset transistor, or a transistor for a logic circuit for reading out electrons generated in photoelectric converter 111, for example.

Transistor 160 includes gate insulating film 120, gate electrode 121, underlying oxide film 131, and sidewall 140.

Gate insulating film 120 is a gate insulating film for transistor 160.

Gate electrode 121 is a gate electrode for transistor 160. Gate electrode 121 is made of polysilicon, for example.

Underlying oxide film 131 is a film for forming sidewall 140, Underlying oxide film 131 is made of the same material as that for underlying oxide film 130.

Sidewall 140 is disposed in sides of transistor 160 (more specifically, gate electrode 121), and is a film for laterally supporting transistor 160 (more specifically, gate electrode 121). In other words, transistor 160 (more specifically, gate electrode 121) includes sidewall 140 in its sides, sidewall 140 being disposed in logic region 210 and made of an insulating material. Sidewall 140 is configured with the same material (insulating material) as those for anti-reflective film 151 and first liner film 152.

First liner film 152 is a film for a so-called liner to stop etching during formation of wiring not illustrated in semiconductor substrate 110. First liner film 152 is made of the same insulating material as that of anti-reflective film 151, and is a nitride film, for example. First liner film 152 is disposed above main surface 112 of semiconductor substrate 110 in logic region 210, i.e., above logic region 210. Specifically, first liner film 152 is disposed in contact with transistor 160 and main surface 112 of semiconductor substrate 110.

In the present embodiment, first liner film 152 and anti-reflective film 151 are integrally formed. In other words, anti-reflective film 151 and first liner film 152 are formed as a single film (insulating film 150) above main surface 112 of semiconductor substrate 110.

Insulating film 150 is a film disposed above main surface 112 of semiconductor substrate 110. Insulating film 150 is a nitride film, for example.

Another region 220 is a region which is neither pixel region 200 nor logic region 210 in semiconductor substrate 110, in other words, a region in which the transistor and the photoelectric converter such as APD are not disposed. Second liner film 153 made of the above-mentioned insulating material is disposed above main surface 112 of semiconductor substrate 110 in another region 220. In another region 220, for example, not only a transistor of the same type as that of transistor 160 but also a transistor of a different type are not disposed. For example, in the case where transistor 160 is a transfer transistor, not only a transfer transistor but also another transistor such as a reset transistor are not disposed in another region 220.

Second liner film 153 is a film for a so-called liner to stop etching during formation of wiring not illustrated in semiconductor substrate 110, Second liner film 153 is made of the same insulating material as those for anti-reflective film 151 and first liner film 152, and is a nitride film, for example. Second liner film 153 is formed in contact with main surface 112 of semiconductor substrate 110.

Second liner film 153 is integrally formed with first liner film 152 and anti-reflective film 151, In other words, anti-reflective film 151, first liner film 152, and second liner film 153 are formed as a single film (insulating film 150) above main surface 112 of semiconductor substrate 110.

First liner film 152 and second liner film 153 have the same thickness.

Here, thickness A of anti-reflective film 151 (the width in the Z-axial direction in the present embodiment), thickness B of sidewall 140 (the width in the X-axial direction in the present embodiment), and thickness C (the width in the Z-axial direction in the present embodiment) of first liner film 152 (and second liner film 153) have a relation represented by Expression (1).

thickness A≥thickness B+thickness C Expression (1)

In other words, thickness A of anti-reflective film 151 is larger than or equal to the sum of thickness B of sidewall 140 and thickness C of first liner film 152.

To be noted, the left side of Expression (1) may include the thickness (the width in the X-axial direction in the present embodiment) of underlying oxide film 131, and the right side of Expression (1) may include the thickness (the width in the Z-axial direction in the present embodiment) of underlying oxide film 130.

For example, in a cross-sectional view, thickness B of sidewall 140 may be a difference between the largest width of underlying oxide film 131 in the X-axial direction and the length of underlying oxide film 131 in the X-axial direction extending from sidewall 140 to gate electrode 121.

Color filter 170 is disposed facing main surface 112 of semiconductor substrate 110 to partially block light entering APD 111. For example, color filter 170 is placed on a layer (not illustrated) stacked on anti-reflective film 151. Alternatively, color filter 170 may be disposed above APD 111 while being held by a housing (not illustrated) included in semiconductor device 100. Alternatively, color filter 170 may be placed on anti-reflective film 151. For example, color filter 170 blocks light having a wavelength of less than 650 nm, and transmits light having a wavelength of 650 nm or more,

### [Manufacturing Process]

### Example

Subsequently, the method of manufacturing semiconductor device 100 will be described in detail.

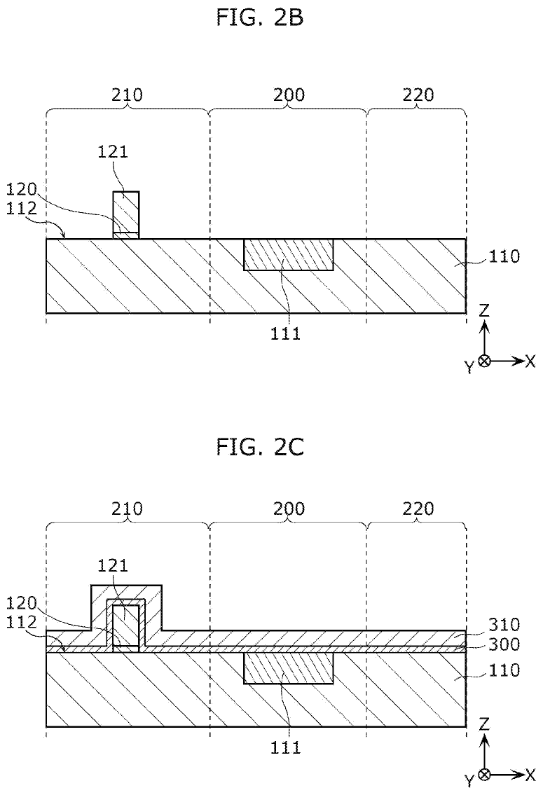

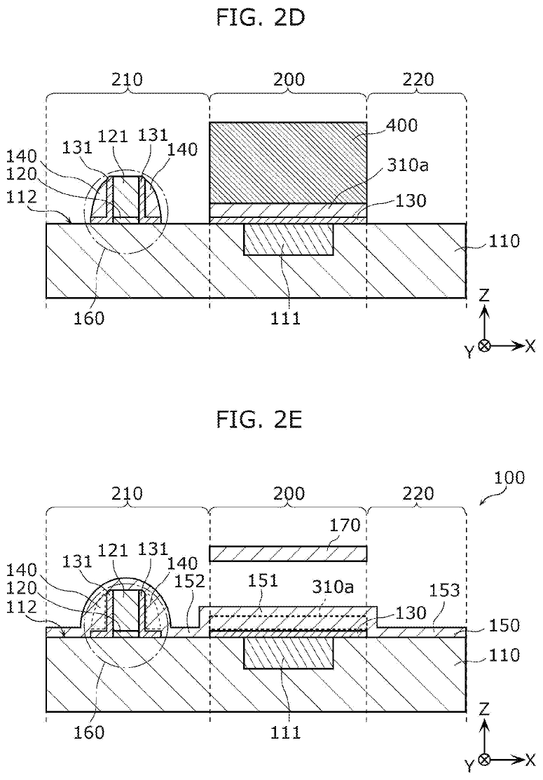

FIGS. 2A to 2E are cross-sectional views illustrating a method of manufacturing semiconductor device 100 according to an embodiment.

Initially, APD 111 is formed in pixel region 200 in semiconductor substrate 110 (photoelectric converter forming step), For example, as illustrated in FIG. 2A, in semiconductor substrate 110 of a P-type containing boron, APD 111 is formed in pixel region 200 in contact with main surface 112 of semiconductor substrate 110. To form APD 111, As is injected into semiconductor substrate 110 in multiple stages with 2000 keV (dose amount: 2E12 cm⁻²), 1000 key (dose amount: 4E12 cm⁻²), 500 keV (dose amount: 6E12 cm⁻²), and 100 keV (dose amount: 1E13 cm⁻²) in this order, for example. APD 111 is formed with As (N-type) and boron (P-type) contained in semiconductor substrate 110.

In the next step, gate electrode 121 included in transistor 160 is formed in logic region 210 of semiconductor substrate 110 (electrode forming step). Specifically, as illustrated in FIG. 2B, gate insulating film 120 having a thickness of 5 nm is formed above main surface 112 of semiconductor substrate 110 in logic region 210. Gate electrode 121 made of polysilicon and having a thickness of 140 nm is formed above top surface of gate insulating film 120.

In the next step, insulating film 310 is formed by depositing an insulating material above main surface 112 of semiconductor substrate 110 (first film forming step). Specifically, as illustrated in FIG. 2C, underlying oxide film 300 is formed above main surface 112 of semiconductor substrate 110 to have a thickness of 20 nm. Insulating film 310 is formed to have a thickness of 60 nm, by depositing an insulating material (such as a nitride) above main surface 112 of semiconductor substrate 110 (more specifically, top surface of underlying oxide film 300).

In the next step, sidewall 140 made of the insulating material is formed in sides of gate electrode 121 by etching insulating film 310 (etching step). Specifically, as illustrated in FIG. 2D, resist mask 400 is formed (disposed) in pixel region 200 by a lithographic technique, followed by etching (sidewall etching). Thereby, sidewall 140 is formed in the sides (lateral surfaces) of gate electrode 121 in logic region 210 with underlying oxide film 131 interposed therebetween. For example, resist mask 400 is formed by applying a resist onto insulating film 310 and patterning the resist by lithography. Thereby, the components included in transistor 160, such as underlying oxide film 131 and sidewall 140, are formed in logic region 210. In pixel region 200, insulating film 310a is formed above underlying oxide film 130.

Here, in the step (etching step) of forming sidewall 140, pixel region 200 is covered with resist mask 400, and therefore is free from plasma damage caused by sidewall etching. In other words, in the etching step, defects through the manufacturing process are not generated in APD 111.

In the next step, as illustrated in FIG. 2E, insulating film 150 is formed by further depositing an insulating material above main surface 112 of semiconductor substrate 110. Specifically, by further depositing the above-mentioned insulating material above main surface 112 of semiconductor substrate 110, anti-reflective film 151 disposed above main surface 112 of semiconductor substrate 110 in pixel region 200 and made of the insulating material and first liner film 152 disposed above main surface 112 of semiconductor substrate 110 in logic region 210 and made of the insulating material are formed (second film forming step). In the second film forming step, further, second liner film 153 made of the insulating material is formed above main surface 112 of semiconductor substrate 110 in another region 220 in which the transistor and the photoelectric converter such as an APD are not disposed.

Thereby, anti-reflective film 151, first liner film 152, and second liner film 153 are integrally formed above main surface 112 of semiconductor substrate 110. In other words, anti-reflective film 151 is formed through the second film forming step in which the insulating material is further deposited above the insulating material deposited in the first film forming step. For example, in the second film forming step, first liner film 152 and second liner film 153 are formed to have the same thickness, which is 15 nm.

The first film forming step, the etching step, and the second film forming step are performed such that thickness A of anti-reflective film 151 is larger than or equal to the sum of thickness B of sidewall 140 and thickness C of first liner film 152.

After the second film forming step, the wiring for semiconductor substrate 110 is formed by a wiring process, and color filter 170 is disposed above semiconductor substrate 110 (more specifically, above APD 111) (disposing step), thereby manufacturing semiconductor device 100.

Although not illustrated, an off-set spacer made from an oxide film may be formed on lateral surfaces of gate electrode 121 in transistor 160 between the step illustrated in FIG. 2B and the step illustrated in FIG. 2C. Although not particularly limited, the thickness of the off-set spacer may be about 15 nm, for example.

Although not clearly illustrated in FIGS. 2B to 2E, the oxide film (silicon oxide film) left during the formation of gate insulating film 120 is also present above main surface 112 of semiconductor substrate 110.

According to the method of manufacturing semiconductor device 100, about 40 nm of the oxide film and about 75 nm of the nitride film are present above main surface 112 of semiconductor substrate 110 in pixel region 200. For this reason, a film which functions as anti-reflective film 151 optimal to near-infrared (IR) light at 940 nm entering pixel region 200 is formed, for example.

### Comparative Example

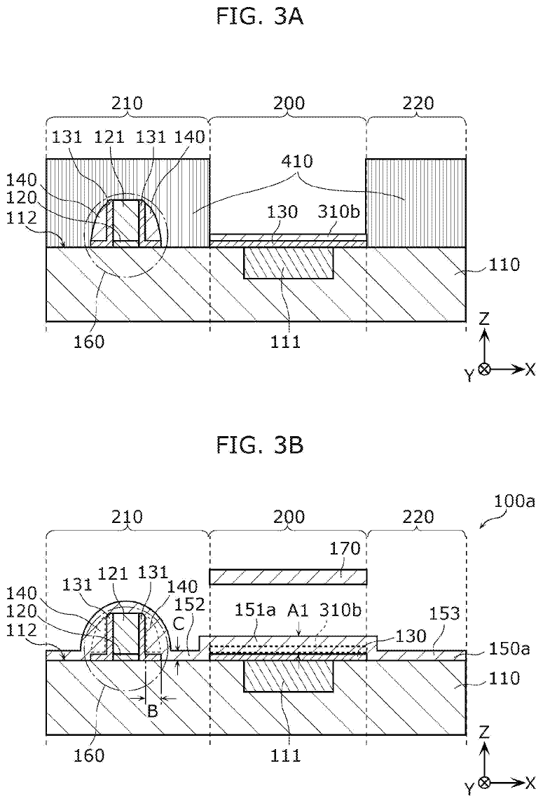

FIGS. 3A and 3B are diagrams illustrating a method of manufacturing semiconductor device 100a according to Comparative Example. In the following description, the description of the procedure identical to that in Example is partially simplified or omitted in some cases.

Also in the method of manufacturing semiconductor device 100a according to Comparative Example, the process illustrated in FIGS. 2A to 2D are initially performed as in the method of manufacturing semiconductor device 100 according to the embodiment.

Specifically, initially, as illustrated in FIG. 2A, in semiconductor substrate 110 of the P-type containing boron, APD 111 is formed in pixel region 200 in contact with main surface 112 of semiconductor substrate 110 (photoelectric converter forming step).

In the next step, as illustrated in FIG. 2B, gate insulating film 120 is formed above main surface 112 of semiconductor substrate 110 in logic region 210. Gate electrode 121 is formed above the top surface of gate insulating film 120 (electrode forming step).

In the next step, as illustrated in FIG. 2C, insulating film 310 is formed by depositing an insulating material above main surface 112 of semiconductor substrate 110 (first film forming step).

In the next step, as illustrated in FIG. 2D, sidewall 140 made of the same insulating material is formed in sides of gate electrode 121 by etching insulating film 310 (etching step).

Here, in the step (etching step) of forming sidewall 140, pixel region 200 is covered with resist mask 400, and therefore is free from plasma damage caused by sidewall etching. In other words, in the etching step, defects through the manufacturing process are not generated in APD 111.

In the next step, as illustrated in FIG. 3A, resist mask 410 having an opening corresponding to pixel region 200 in a top surface view is formed, followed by wet etching. Thus, insulating film 310b is formed by reducing the thickness of insulating film 310a in pixel region 200 (film thickness reducing step). For example, resist mask 410 is formed by applying a resist onto main surface 112, insulating film 310a, gate electrode 121, and sidewall 140 and patterning the resist by lithography. Thus, the film thickness reducing step is performed in the method of manufacturing semiconductor device 100a according to Comparative Example. Thereby, anti-reflective film 151a having a thickness smaller than that of anti-reflective film 151 is formed.

In the next step, as illustrated in FIG. 3B, insulating film 150a is formed by further depositing an insulating material above main surface 112 of semiconductor substrate 110. Specifically, by further depositing the above-mentioned insulating material above main surface 112 of semiconductor substrate 110, anti-reflective film 151a disposed above main surface 112 of semiconductor substrate 110 in pixel region 200 and made of the above-mentioned insulating material and first liner film 152 disposed above main surface 112 of semiconductor substrate 110 in logic region 210 and made of the above-mentioned insulating material are formed (second film forming step). In the second film forming step, further, in semiconductor substrate 110, second liner film 153 made of the above-mentioned insulating material is formed above main surface 112 of semiconductor substrate 110 in another region 220 in which the transistor and the photoelectric converter such as an APD are not disposed. Thereby, anti-reflective film 151a, first liner film 152, and second liner film 153 are integrally formed above main surface 112 of semiconductor substrate 110. In other words, anti-reflective film 151a, first liner film 152, and second liner film 153 are formed as a single film (insulating film 150a) above main surface 112 of semiconductor substrate 110.

After the second film forming step, the wiring for semiconductor substrate 110 is formed by a wiring process, and color filter 170 is disposed above semiconductor substrate 110 (more specifically, above APD 111) (disposing step), thereby manufacturing semiconductor device 100a.

The oxide film (silicon oxide film) not clearly illustrated in FIGS. 3A and 3B is also present above main surface 112 of semiconductor substrate 110, the oxide film being left during formation of underlying oxide film 131 in contact with sidewall 140 and gate insulating film 120.

As described above, the film thickness reducing step is performed in the method of manufacturing semiconductor device 100a according to Comparative Example while the film thickness reducing step is not performed in the method of manufacturing semiconductor device 100 according to Example.

### <Action>

The anti-reflective films formed in pixel region 200 will be described by way of Example and Comparative Example.

When light enters APD 111, APD 111 absorbs the light, and photoelectrically converts the absorbed light. A function can be expected in the film formed in pixel region 200 (e.g., a nitride film) as a film for preventing reflection of light (incident light) entering pixel region 200. In other words, anti-reflective film 151 present above APD 111 can prevent reflection of light entering APD 111. For this reason, a reduction in conversion efficiency of semiconductor device 100 can be suppressed.

For example, consider a case where the incident light is visible light having a wavelength of 550 nm. When the silicon oxide film present above main surface 112 of semiconductor substrate 110 in pixel region 200 has a thickness of 40 nm, the optimal thickness of the nitride film to function as anti-reflective film 151 is 30 nm.

As described above, the oxide film (not clearly illustrated) left during formation of underlying oxide film 131 in contact with sidewall 140 and gate insulating film 120 is also present above main surface 112 of semiconductor substrate 110.

The film for a liner (first liner film 152 and second liner film 153) is a film for introducing distortion stress to logic region 210 to improve the properties of transistor 160 or for functioning as an etching stopper film during contact etching.

When the thickness of the film for a liner is 15 nm, for example, in order to form a film having a thickness of 30 nm which functions as an optimal anti-reflective film, the thickness of the film present in pixel region 200 needs to be controlled to 15 nm before formation of the film for a liner.

Sidewall 140 is formed to have thickness B of typically about 50 nm. For this reason, for example, the thickness of sidewall 140 is adjusted by performing the film thickness reducing step on the insulating film as illustrated in FIG. 3A. In semiconductor device 100a manufactured by performing the film thickness reducing step, thickness A1 of anti-reflective film 151a, thickness B of sidewall 140, and thickness C of first liner film 152 have the following relation, resulting in optimal thickness A1 of the film in pixel region 200 as a film for preventing reflection of light (anti-reflective film 151a).

thickness A1<thickness B+thickness C Expression (2)

However, compared to the method of manufacturing semiconductor device 100 manufactured to satisfy the relation represented by Expression (1) above, process cost is increased due to the additional step illustrated in FIG. 3A, and a variation in optical properties accompanied by a variation in final thickness of anti-reflective film 151a occurs in the method of manufacturing semiconductor device 100a to satisfy the relation represented by Expression (2). Because of process damage introduced to pixel region 200 in semiconductor substrate 110, the dark current to generate may be increased.

Thus, in the method of manufacturing semiconductor device 100, as illustrated in FIGS. 2A to 2E, for example, the films are formed in the first film forming step and the second film forming step to satisfy the relation represented by Expression (1), by depositing the same insulating material FIG. 3A, without performing etching (film thickness reducing step). Such an operation can reduce the process damage to APD 111, and enables manufacturing of semiconductor device 100 including anti-reflective film 151 having an optimal thickness to suppress reflection of incident light. In other words, in semiconductor device 100, the quantity of light entering APD 111 can be increased (that is, the light collection efficiency can be improved), and generation of the dark current can be suppressed. The light collection efficiency here indicates the quantity of light entering APD 111 without reflected to the quantity of light radiated to APD 111, for example.

In the method of manufacturing a semiconductor device according to Example, thickness A approximately corresponds to the sum of thickness B and thickness C. In other words, the etching step is performed such that the thickness (width in the Z-axial direction) of insulating film 310a approximately corresponds to thickness B of sidewall 140. However, in the etching step, etching is performed in some cases such that thickness B of sidewall 140 is smaller than the thickness (width in the Z-axial direction) of insulating film 310a. For this reason, as represented by Expression (1) above, thickness A of anti-reflective film 151 is larger than or equal to the sum of thickness B of sidewall 140 and thickness C of first liner film 152.

### [Effects]

As described above, semiconductor device 100 according to the embodiment includes semiconductor substrate 110 including pixel region 200 in which APD 111 is disposed, and logic region 210 different from pixel region 200; transistor 160 which is disposed in logic region 210 and includes sidewall 140 in sides, sidewall 140 being made of an insulating material; anti-reflective film 151 which is disposed above main surface 112 of semiconductor substrate 110 in pixel region 200 and made of the insulating material; and first liner film 152 which is disposed above main surface 112 of semiconductor substrate 110 in logic region 210 and made of the insulating material. Anti-reflective film 151 and first liner film 152 are integrally formed. Thickness A of anti-reflective film 151 is larger than or equal to the sum of thickness B of sidewall 140 and thickness C of first liner film 152.

As described above, by forming anti-reflective film 151 without performing the film thickness reducing step, thickness A of anti-reflective film 151 is controlled to be larger than or equal to the sum of thickness B of sidewall 140 and thickness C of first liner film 152. In other words, because semiconductor device 100 in which thickness A of anti-reflective film 151 is larger than or equal to the sum of thickness B of sidewall 140 and thickness C of first liner film 152 is not subjected to the film thickness reducing step, process damage during formation of anti-reflective film 151 is not introduced in pixel region 200, thereby suppressing generation of the dark current. For this reason, in semiconductor device 100 thus manufactured, the light collection efficiency can be improved because anti-reflective film 151 is included in semiconductor device 100, and generation of the dark current can be suppressed because the film thickness reducing step is not performed.

Moreover, the insulating material is a nitride, for example. In such a configuration, a single film (insulating film 150) which prevents reflection of light and is configured with anti-reflective film 151 and first liner film 152 integrally formed can be formed above semiconductor substrate 110 using a process in a conventional method of manufacturing a complementary met& oxide semiconductor (CMOS). In other words, anti-reflective film 151 can be simply manufactured by the convention& manufacturing method.

Moreover, APD 111 photoelectrically converts light having a wavelength of 650 nm or more, for example.

For example, consider a case where APD 111 photoelectrically converts visible light having a wavelength of 550 nm. In this case, the optimal thickness of the film when it functions as anti-reflective film 151 is 30 nm, for example. Here, as the wavelength of light photoelectrically converted by APD 111 is longer, the optimal film thickness when anti-reflective film 151 functions (that is, reflects the target light) is larger. For example, compared to the method of manufacturing semiconductor device 100a according to Comparative Example, anti-reflective film 151 is thicker in the method of manufacturing semiconductor device 100 according to Example, in which the film thickness reducing step is not performed. For this reason, semiconductor device 100 is suitable for applications to photoelectric conversion of light having a long wavelength, for example, light having a wavelength of 650 nm or more.

Moreover, the thickness of anti-reflective film 151 is 70 nm or more, for example.

Anti-reflective film 151 having a thickness of 70 nm or more reduces reflection of light having a wavelength of 650 nm or more. For this reason, semiconductor device 100 having such a configuration is more suitable for applications to photoelectric conversion of light having a long wavelength, for example, light having a wavelength of 650 nm or more.

Moreover, semiconductor device 100 further includes color filter 170 which blocks light having a wavelength of less than 650 nm, for example.

In such a configuration, semiconductor device 100 can precisely detect light having the target wavelength when used in applications to photoelectric conversion of light having a wavelength of 650 nm or more, for example.

Moreover, for example, semiconductor substrate 110 further includes another region 220 in which the transistor and the photoelectric converter such as an APD are not disposed. For example, second liner film 153 made of the insulating material is disposed above main surface 112 of semiconductor substrate 110 in another region 220. Anti-reflective film 151, first liner film 152, and second liner film 153 are integrally formed. First liner film 152 and second liner film 153 are identical in thickness.

As described above, for example, in the method of manufacturing semiconductor device 100 according to Example, anti-reflective film 151, first liner film 152, and second liner film 153 are integrally formed, Because first liner film 152 and second liner film 153 are formed above main surface 112 of semiconductor substrate 110 by the same process, first liner film 152 and second liner film 153 have the same thickness. For this reason, semiconductor device 100 in which anti-reflective film 151, first liner film 152, and second liner film 153 are integrally formed and first liner film 152 and second liner film 153 have the same thickness can be simply manufactured using the process in the conventional method of manufacturing a CMOS.

Moreover, the method of manufacturing semiconductor device 100 according to an embodiment includes (i) forming APD 111 in pixel region 200 in semiconductor substrate 110 (photoelectric converter forming step); (ii) forming gate electrode 121 included in transistor 160 in logic region 210 different from pixel region 200 in semiconductor substrate 110 (electrode forming step); (iii) forming insulating film 310 by depositing an insulating material above main surface 112 of semiconductor substrate 110 (first film forming step); (iv) forming sidewall 140 made of the insulating material in sides of gate electrode 121 by etching insulating film 310 (etching step); and (v) forming anti-reflective film 151 and first liner film 152 by further depositing the insulating material above main surface 112 of semiconductor substrate 110 (second film forming step), anti-reflective film 151 being disposed above main surface 112 of semiconductor substrate 110 in pixel region 200 and made of the insulating material, first liner film 152 being disposed above main surface 112 of semiconductor substrate 110 in logic region 210 and made of the insulating material.

Thereby, using the process in the conventional method of manufacturing a CMOS, semiconductor device 100 including semiconductor substrate 110 including pixel region 200 and logic region 210 can be manufactured without introducing process damage to pixel region 200, while the dark current is suppressed. Furthermore, because anti-reflective film 151 having a thickness optimal to the incident light is present in pixel region 200, the light collection efficiency is not reduced. Furthermore, because an additional step for forming anti-reflective film 151 having an optimal thickness is unnecessary, an increase in process cost can be suppressed. Moreover, occurrence of a variation in optical properties accompanied by a variation in final thickness of anti-reflective film 151 can be suppressed. In other words, by the method of manufacturing a semiconductor device according to according to the embodiment, semiconductor device 100 can be manufactured in which the quantity of light entering APD 111 is increased (that is, the light collection efficiency can be improved), and generation of the dark current can be suppressed.

Moreover, for example, to control such that thickness A of anti-reflective film 151 is larger than or equal to the sum of thickness B of sidewall 140 and thickness C of first liner film 152, thickness of insulating film 310 in the first film forming step and the etching rate in the etching step are appropriately set.

Thereby, using the process in the conventional method of manufacturing a CMOS, a single film (insulating film 150) in which reflection of light is prevented and anti-reflective film 151 and first liner film 152 are integrally formed can be formed above semiconductor substrate 110.

Moreover, for example, the first film forming step and the second film forming step are performed such that anti-reflective film 151 has a thickness of 70 nm or more.

Thereby, anti-reflective film 151 having a thickness of 70 nm or more reduces reflection of light having a wavelength of 650 nm or more, for example. For this reason, semiconductor device 100 having such a configuration is more suitable for applications to photoelectric conversion of light having a long wavelength, for example, light having a wavelength of 650 nm or more.

Moreover, for example, the method of manufacturing semiconductor device 100 according to the embodiment further includes disposing color filter 170 which blocks light having a wavelength of less than 650 nm (disposing step).

Thereby, when semiconductor device 100 is used in applications to photoelectric conversion of light having a wavelength of 650 nm or more, for example, semiconductor device 100 which can precisely detect light having the target wavelength can be manufactured.

Moreover, for example, in the second film forming step, second liner film 153 made of the insulating material is further formed above main surface 112 of semiconductor substrate 110 in another region 220 in which the transistor and the photoelectric converter such as an APD are not disposed. Moreover, for example, anti-reflective film 151, first liner film 152, and second liner film 153 are integrally formed. Moreover, for example, first liner film 152 and second liner film 153 are identical in thickness.

Thereby, using the process in the conventional method of manufacturing a CMOS, anti-reflective film 151, first liner film 152, and second liner film 153 can be simply manufactured.

### Other Embodiments

The semiconductor device according to the embodiment and the like have been described above, but the embodiments should not be construed as limitations to the present disclosure.

For example, the numeric values used in the descriptions of the embodiments all are exemplary for specifically describing the present disclosure, and the present disclosure is not limited to the exemplified numeric values.

Although the main materials constituting the layers of the laminate structure included in the semiconductor device have been exemplified in the embodiments, the layers of the laminate structure included in the semiconductor device may contain other materials in the ranges enabling implementation of the function identical to the laminate structure according to the embodiments.

Besides, the present disclosure also covers embodiments obtained from a variety of modifications of the embodiments conceived and made by persons skilled in the art, or embodiments implemented with any combination of the components and the functions in the embodiments without departing from the gist of the present disclosure. For example, the present disclosure may be implemented as an imaging apparatus including semiconductor devices according to the present disclosure arranged in a matrix and a method of manufacturing the imaging apparatus.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The present disclosure can be applied to semiconductor devices which include a pixel region and a logic region and can have improved light collection efficiency while generation of the dark current can be suppressed, and a method of manufacturing the same.

1. A semiconductor device comprising:
a silicon semiconductor substrate including a first region in which a photoelectric converter is disposed, and a second region different from the first region;
a transistor which is disposed in the second region and includes a sidewall made of an insulating material;
an anti-reflective film which is disposed above a main surface of the silicon semiconductor substrate in the first region and is made of the insulating material; and
a first liner film which is disposed above the main surface of the silicon semiconductor substrate in the second region and is made of the insulating material,
wherein the anti-reflective film and the first liner film are integrally formed, and
a thickness of the anti-reflective film is larger than or equal to a sum of a thickness of the sidewall and a thickness of the first liner film.

2. The semiconductor device according to claim 1,
wherein the insulating material is a nitride.

3. The semiconductor device according to claim 1,
wherein the photoelectric converter photoelectrically converts light having a wavelength of 650 nm or more.

4. The semiconductor device according to claim 1,
wherein the thickness of the anti-reflective film is 70 nm or more.

5. The semiconductor device according to claim 1, further comprising:
a color filter which blocks light having a wavelength of less than 650 nm.

6. The semiconductor device according to claim 1,
wherein the silicon semiconductor substrate further includes a third region in which the transistor and the photoelectric converter are not disposed,
a second liner film made of the insulating material is disposed above the main surface of the silicon semiconductor substrate in the third region,
the anti-reflective film, the first liner film, and the second liner film are integrally formed, and
the first liner film and the second liner film are identical in thickness.

7. A method of manufacturing a semiconductor device, the method comprising:
(i) forming a photoelectric converter in a first region in a silicon semiconductor substrate;
(ii) forming a gate electrode in a second region different from the first region in the silicon semiconductor substrate, the gate electrode being included in a transistor;
(iii) forming an insulating film by depositing an insulating material above a main surface of the silicon semiconductor substrate;
(iv) forming a sidewall made of the insulating material in sides of the gate electrode by etching the insulating film; and
(v) forming an anti-reflective film and a first liner film by further depositing the insulating material above the main surface of the silicon semiconductor substrate, the anti-reflective film being disposed above the main surface of the silicon semiconductor substrate in the first region and made of the insulating material, the first liner film being disposed above the main surface of the silicon semiconductor substrate in the second region and made of the insulating material.

8. The method of manufacturing a semiconductor device according to claim 7,
wherein a thickness of the anti-reflective film is larger than or equal to a sum of a thickness of the sidewall and a thickness of the first liner film.

9. The method of manufacturing a semiconductor device according to claim 7,
wherein the insulating material is a nitride.

10. The method of manufacturing a semiconductor device according to claim 7,
wherein the photoelectric converter photoelectrically converts light having a wavelength of 650 nm or more.

11. The method of manufacturing a semiconductor device according to claim 7,
wherein a thickness of the anti-reflective film is 70 nm or more.

12. The method of manufacturing a semiconductor device according to claim 7, further comprising:
disposing a color filter which blocks light having a wavelength of less than 650 nm.

13. The method of manufacturing a semiconductor device according to claim 7,
wherein (v) further includes forming a second liner film made of the insulating material above the main surface of the silicon semiconductor substrate in a third region in which the transistor and the photoelectric converter are not disposed,
the anti-reflective film, the first liner film, and the second liner film are integrally formed, and
the first liner film and the second liner film are identical in thickness.
